(19) United States
(12) Patent Application Publication
(10) Pub. No.: US 2024/0258080 A1
(43) Pub. Date: Aug. 1, 2024

(54) FOCUS RING AND PLASMA TREATMENT DEVICE

(71) Applicant: KYOCERA Corporation, Kyoto-shi, Kyoto (JP)

(72) Inventor: Masao YOSHIDA, Higashiomi-shi, Shiga (JP)

(21) Appl. No.: 18/564,558

(22) PCT Filed: May 25, 2022
(86) PCT No.: PCT/JP2022/021457

§ 371 Date: Nov. 27, 2023

(30) Foreign Application Priority Data
May 27, 2021 (JP) 2021-089598

(51) Int. Cl. H01J 37/32

(52) U.S. Cl. CPC H01J 37/32642

(57) ABSTRACT

A focus ring according to the present disclosure includes a placement surface accommodating a substrate to be treated and facing a lower surface of the substrate to be treated, and a back surface located on an opposite side to the placement surface. An average value of a cutting level difference (Rδc) representing a difference between a cutting level at a load-length ratio of 25% in a roughness curve and a cutting level at a load-length ratio of 75% in the roughness curve is greater in a supported portion of the back surface supported by one support member than in the placement surface.

### TECHNICAL FIELD

The present disclosure relates to a focus ring and a plasma treatment device.

### BACKGROUND OF INVENTION

For example, in a conventional plasma treatment device described in Patent Document 1, when the temperature in a plasma treatment chamber increases due to the conversion of a gas into plasma, a large temperature difference occurs between a front surface and a back surface of an edge ring (focus ring). When a placement surface accommodating a substrate to be treated and facing a lower surface of the substrate to be treated is formed to have a step from the surface, the temperature difference causes a large displacement at an inner peripheral side end portion of the placement surface. When such a displacement occurs, stably holding the substrate to be treated may not be possible.

### CITATION LIST

### Patent Literature

Patent Document 1: JP 2016-184610 A

### SUMMARY

### Problem to be Solved

In the present disclosure, a focus ring includes a placement surface accommodating a substrate to be treated and facing a lower surface of the substrate to be treated, and a back surface located on an opposite side to the placement surface. An average value of a cutting level difference (Rδc) representing a difference between a cutting level at a load-length ratio of 25% in a roughness curve and a cutting level at a load-length ratio of 75% in the roughness curve is greater in a supported portion of the back surface supported by one support member than in the placement surface.

In the present disclosure, another focus ring includes a placement surface accommodating a substrate to be treated and facing a lower surface of the substrate to be treated, and a back surface located on the opposite side to the placement surface. An average value of a cutting level difference (Rδc) representing a difference between a cutting level at a load-length ratio of 25% in a roughness curve and a cutting level at a load-length ratio of 75% in the roughness curve is greater in a supported portion on the innermost peripheral side of the back surface supported by a plurality of support members than in the placement surface.

In the present disclosure, a plasma treatment device includes the focus ring described above.

### BRIEF DESCRIPTION OF THE DRAWINGS

FIG. 1A illustrates a plan view of a focus ring according to an embodiment of the present disclosure. FIG. 1B is a cross-sectional view illustrating a part of a state in which a substrate to be treated is accommodated in the focus ring according to the embodiment of the present disclosure.

FIG. 2A illustrates a plan view of a focus ring according to another embodiment of the present disclosure. FIG. 2B is a cross-sectional view illustrating a part of a state in which a substrate to be treated is accommodated in the focus ring according to the other embodiment of the present disclosure.

### DESCRIPTION OF EMBODIMENTS

As described above, in a conventional plasma treatment device, when the temperature in a plasma processing chamber increases due to the conversion of a gas into plasma, a large temperature difference occurs between a front surface and a back surface of an edge ring (focus ring). When a large temperature difference occurs, a large displacement occurs at the inner peripheral side end portion of the placement surface. When such a displacement occurs, stably holding the substrate to be treated may not be possible. Therefore, there is a need for a focus ring by which the substrate to be treated is less likely to be damaged, even when the substrate to be treated comes in contact with the placement surface, and that is capable of suppressing displacement occurring at the inner peripheral side end portion of the placement surface, even when the temperature in the plasma treatment chamber increases.

In the focus ring according to the present disclosure, even when the substrate to be treated comes in contact with the placement surface, the substrate to be treated is less likely to be damaged, and even when the temperature in the plasma treatment chamber increases, displacement occurring at the inner peripheral side end portion of the placement surface may be suppressed.

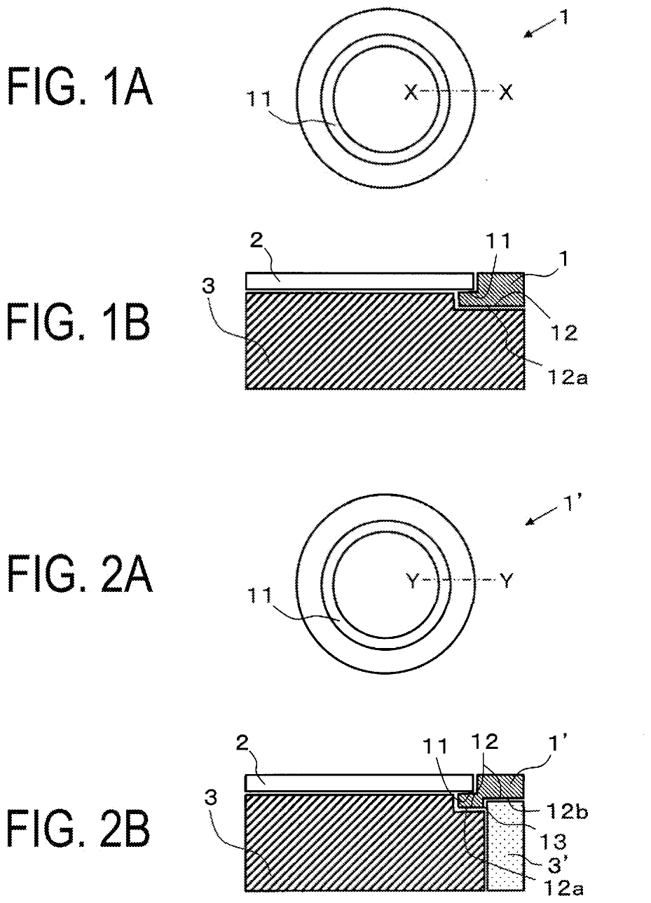

A focus ring according to an embodiment of the present disclosure will be described with reference to FIG. 1. FIG. 1A illustrates a plan view of a focus ring 1 according to an embodiment of the present disclosure. FIG. 1B is a cross-sectional view illustrating a part of a state in which a to-be-treated substrate 2 is accommodated in the focus ring 1 according to the embodiment. Specifically, FIG. 1B is a cross-sectional view illustrating a part of a state in which the to-be-treated substrate 2 is horizontally supported on a support member 3 provided inside the plasma treatment device (inside a plasma treatment chamber such as a chamber constituting the plasma treatment device).

The focus ring 1 according to the embodiment is a member having an annular shape, as illustrated in FIG. 1A. FIG. 1B illustrates a cross section of the focus ring 1 taken along a line X-X illustrated in FIG. 1A. The material of the focus ring 1 is not limited, and examples thereof include ceramics containing, as a main component, a rare earth element oxide such as yttrium oxide, lanthanum oxide, and cerium oxide, a rare earth element aluminum composite oxide, and aluminum oxide. Examples of the rare earth element aluminum composite oxide include yttrium aluminum composite oxides such as YAG (3Y₂O₃*5Al₂O₃), YAM (2Y₂O₃*Al₂O₃), YAL (Y₂O₃*Al₂O₃), and YAP (YAlO₃); erbium aluminum composite oxides such as EAG (Er₃Al₅O₁₂), EAM (Er₄Al₂O₉), and EAP (ErAlO₃); gadolinium aluminum composite oxides such as GdAM (Gd₄Al₂O₉) and GdAP (GdAlO₃); and neodymium aluminum composite oxides such as NdAG (Nd₃Al₅O₁₂), NdAM (Nd₄Al₂O₉), and NdAP (NdAlO₃).

As illustrated in FIGS. 1A and 1B, the focus ring 1 according to the embodiment includes a placement surface 11 and a back surface 12 located on the opposite side to the placement surface 11. The placement surface 11 faces a lower surface of the to-be-treated substrate 2 when the to-be-treated substrate 2 is accommodated. On the other hand, the back surface 12 corresponds to a surface located on the opposite side to the placement surface 11, that is, a surface facing the placement surface 11.

At least a part of the back surface 12 is supported by one support member 3, and a portion facing the support member 3 corresponds to a supported portion 12a. In FIG. 1B, the entire back surface 12 is supported by the support member 3, and thus, the entire back surface 12 corresponds to the supported portion 12a.

In the focus ring 1 according to the embodiment, the supported portion 12a has a greater average value of a cutting level difference (Rδc) than the placement surface 11, where Rδc indicates a difference between a cutting level at a load-length ratio of 25% in a roughness curve and a cutting level at a load-length ratio of 75% in the roughness curve.

As described above, the average value of the cutting level difference (Rδc) of the supported portion 12a is greater than the average value of the cutting level difference (Rδc) of the placement surface 11. Therefore, in the focus ring 1 according to the embodiment, heat rising in the plasma treatment chamber is less likely to be transferred from the supported portion 12a to the support member 3. As a result, the temperature difference generated between the placement surface 11 and the supported portion 12a becomes small, and the displacement occurring at an inner peripheral side end portion of the placement surface 11 can be suppressed. The average value of the cutting level difference (Rδc) of the placement surface 11 is smaller than the average value of the cutting level difference (Rδc) of the supported portion 12a. As a result, even when the to-be-treated substrate 2 comes in contact with the placement surface 11, the to-be-treated substrate 2 is less likely to be damaged. The difference between the average value of the cutting level difference (Rδc) of the supported portion 12a and the average value of the cutting level difference (Rδc) of the placement surface 11 may be 0.03 μm or more.

In the focus ring 1 according to the embodiment, the average value of the cutting level difference (Rδc) of the supported portion 12a is not limited, as long as the average value of the cutting level difference (Rδc) of the supported portion 12a is greater than the average value of the cutting level difference (Rδc) of the placement surface 11. For example, the average value of the cutting level difference (Rδc) of the supported portion 12a may be 0.18 μm or more and 0.42 μm or less. When the average value of the cutting level difference (Rδc) of the supported portion 12a is 0.18 μm or more, an appropriate friction force is generated between the support member 3 and the supported portion 12a. Thus, the focus ring 1 can be stably fixed to the support member 3. On the other hand, when the average value of the cutting level difference (Rδc) of the supported portion 12a is 0.42 μm or less, upon repeatedly attaching and detaching the focus ring 1 to and from the support member 3, particles detaching from the supported portion 12a can be reduced. Therefore, the risk of such particles floating in the plasma treatment chamber can be reduced.

The average value of a root mean square slope (RΔq) in the roughness curve of the supported portion 12a may be greater than the average value of the root mean square slope (RΔq) in the roughness curve of the placement surface 11. As described above, when the average value of the root mean square slope (RΔq) in the roughness curve of the supported portion 12a is greater than the average value of the root mean square slope (RΔq) in the roughness curve of the placement surface 11, heat rising in the plasma treatment chamber is less likely to be transferred from the supported portion 12a to the support member 3 in the focus ring 1 according to the embodiment. As a result, the temperature difference generated between the placement surface 11 and the supported portion 12a becomes small, and the displacement occurring at the inner peripheral side end portion of the placement surface 11 can be suppressed. The average value of the root mean square slope (RΔq) in the roughness curve of the placement surface 11 is smaller than the average value of the root mean square slope (RΔq) in the roughness curve of the supported portion 12a. As a result, even when the to-be-treated substrate 2 comes in contact with the placement surface 11, the to-be-treated substrate 2 is less likely to be damaged. A difference between the average value of the root mean square slope (RΔq) of the supported portion 12a and the average value of the root mean square slope (RΔq) of the placement surface 11 may be 0.001 or more.

The average value of the root mean square slope (RΔq) of the supported portion 12a is not limited, and may be, for example, 0.066 or more and 0.1 or less. When the average value of the root mean square slope (RΔq) of the supported portion 12a is 0.066 or more, an appropriate friction force is generated between the support member 3 and the supported portion 12a. Thus, the focus ring 1 can be stably fixed to the support member 3. On the other hand, if the average value of the root mean square slope (RΔq) of the supported portion 12a is 0.1 or less, upon repeatedly attaching and detaching the focus ring 1 to and from the support member 3, particles detaching from the supported portion 12a can be reduced. Therefore, the risk of such particles floating in the plasma treatment chamber can be reduced.

A focus ring according to another embodiment of the present disclosure will be described with reference to FIG. 2. FIG. 2A illustrates a plan view of a focus ring 1′ according to another embodiment of the present disclosure. FIG. 2B is a cross-sectional view illustrating a part of a state in which the to-be-treated substrate 2 is accommodated in the focus ring 1′ according to the other embodiment. Specifically, FIG. 2B is a cross-sectional view illustrating a part of a state in which the to-be-treated substrate 2 is horizontally supported on the support member 3 provided inside the plasma treatment device (inside a chamber constituting the plasma treatment device).

The focus ring 1′ according to the other embodiment is a member having an annular shape, as illustrated in FIG. 2A. FIG. 2B illustrates a cross section of the focus ring 1′ taken along a line Y-Y illustrated in FIG. 2A. The material of the focus ring 1′ is described in the focus ring 1 according to the embodiment described above, and a detailed description thereof will be omitted.

As illustrated in FIGS. 2A and 2B, the focus ring 1′ according to the other embodiment includes the placement surface 11 and the back surface 12 located on the opposite side to the placement surface 11. The placement surface 11 faces a lower surface of the to-be-treated substrate 2 when the to-be-treated substrate 2 is accommodated. On the other hand, the back surface 12 corresponds to a surface located on the opposite side to the placement surface 11, that is, a surface facing the placement surface 11.

At least a part of the back surface 12 is supported by two support members 3 and 3′, and portions of the back surface 12 facing the support members 3 and 3′ correspond to supported portions 12a and 12b. As illustrated in FIG. 2B, the focus ring 1′ according to the other embodiment is different from the focus ring 1 according to the embodiment in that the focus ring 1′ is supported by the two support members 3 and 3′. The focus ring 1′ according to the other embodiment is supported by the two support members 3 and 3′. However, the focus ring 1′ may be supported by three or more support members.

In the focus ring 1′ according to the other embodiment, the supported portion 12a on the innermost peripheral side among the supported portions 12a and 12b present in the back surface 12 has a greater average value of the cutting level difference (Rδc) than the placement surface 11, where Rδc indicates a difference between a cutting level at a load-length ratio of 25% in a roughness curve and a cutting level at a load-length ratio of 75% in the roughness curve.

As described above, the average value of the cutting level difference (Rδc) of the supported portion 12a on the innermost peripheral side is greater than the average value of the cutting level difference (Rδc) of the placement surface 11. Therefore, in the focus ring 1′ according to the other embodiment, heat rising in the plasma treatment chamber is less likely to be transferred to the support member 3 from the supported portion 12a on the innermost peripheral side. As a result, the temperature difference generated between the placement surface 11 and the supported portion 12a on the innermost peripheral side becomes small, and the displacement occurring at the inner peripheral side end portion of the placement surface 11 can be suppressed. The average value of the cutting level difference (Rδc) of the placement surface 11 is smaller than the average value of the cutting level difference (Rδc) of the supported portion 12a on the innermost peripheral side. As a result, even when the to-be-treated substrate 2 comes in contact with the placement surface 11, the to-be-treated substrate 2 is less likely to be damaged.

In the focus ring 1′ according to the other embodiment, the average value of the cutting level difference (Rδc) of the supported portion 12a on the innermost peripheral side is not limited, as long as the average value of the cutting level difference (Rδc) of the supported portion 12a on the innermost peripheral side is greater than the average value of the cutting level difference (Rδc) of the placement surface 11. The average value of the cutting level difference (Rδc) of the supported portion 12a on the innermost peripheral side may be 0.18 μm or more and 0.42 μm or less. When the average value of the cutting level difference (Rδc) of the supported portion 12a on the innermost peripheral side is 0.18 μm or more, an appropriate friction force is generated between the support member 3 and the supported portion 12a on the innermost peripheral side. Thus, the focus ring 1′ can be stably fixed to the support member 3. On the other hand, when the average value of the cutting level difference (Rδc) of the supported portion 12a on the innermost peripheral side is 0.42 μm or less, upon repeatedly attaching and detaching the focus ring 1′ to and from the support member 3, particles detaching from the supported portion 12a on the innermost peripheral side can be reduced. Therefore, the risk of such particles floating in the plasma treatment chamber can be reduced.

The average value of the cutting level difference (Rδc) of a supported portion other than the supported portion 12a on the innermost peripheral side (the supported portion 12b in FIG. 2B) is not limited, and may be, for example, 0.18 μm or more and 0.42 μm or less, which is the same as or similar to the average value of the cutting level difference (Rδc) of the supported portion 12a on the innermost peripheral side.

The average value of the root mean square slope (RΔq) in the roughness curve of the supported portion 12a on the innermost peripheral side may be greater than the average value of the root mean square slope (RΔq) in the roughness curve of the placement surface 11. As described above, when the average value of the root mean square slope (RΔq) in the roughness curve of the supported portion 12a on the innermost peripheral side is greater than the average value of the root mean square slope (RΔq) in the roughness curve of the placement surface 11, heat rising in the plasma treatment chamber is less likely to be transferred from the supported portion 12a on the innermost peripheral side to the support member 3 in the focus ring 1′ according to the other embodiment. As a result, the temperature difference generated between the placement surface 11 and the supported portion 12a on the innermost peripheral side becomes small, and the displacement occurring at the inner peripheral side end portion of the placement surface 11 can be suppressed. The average value of the root mean square slope (RΔq) in the roughness curve of the placement surface 11 is smaller than the average value of the root mean square slope (RΔq) in the roughness curve of the supported portion 12a on the innermost peripheral side. As a result, even when the to-be-treated substrate 2 comes in contact with the placement surface 11, the to-be-treated substrate 2 is less likely to be damaged.

The average value of the root mean square slope (RΔq) of the supported portion 12a on the innermost peripheral side is not limited, and may be, for example, 0.066 or more and 0.1 or less. When the average value of the root mean square slope (RΔq) of the supported portion 12a on the innermost peripheral side is 0.066 or more, an appropriate friction force is generated between the support member 3 and the supported portion 12a on the innermost peripheral side. Thus, the focus ring 1′ can be stably fixed to the support member 3. On the other hand, if the average value of the root mean square slope (RΔq) of the supported portion 12a on the innermost peripheral side is 0.1 or less, upon repeatedly attaching and detaching the focus ring 1′ to and from the support member 3, particles detaching from the supported portion 12a on the innermost peripheral side can be reduced. Therefore, the risk of such particles floating in the plasma treatment chamber can be reduced.

The average value of the root mean square slope (RΔq) of a supported portion other than the supported portion 12a on the innermost peripheral side (the supported portion 12b in FIG. 2B) is not limited, and may be, for example, 0.066 or more and 0.1 or less, which is the same as or similar to the average value of the root mean square slope (RΔq) of the supported portion 12a on the innermost peripheral side.

The focus ring according to the present disclosure may include a circumferential surface 13, as illustrated in FIG. 2B. Specifically, the circumferential surface 13 extends upward from the back surface 12 and faces the support member 3′. The circumferential surface 13 preferably has a greater average value of the cutting level difference (Rδc) than the placement surface 11, where Rδc indicates a difference between the cutting level at a load-length ratio of 25% in a roughness curve and the cutting level at a load-length ratio of 75% in the roughness curve.

As described above, the average value of the cutting level difference (Rδc) of the circumferential surface 13 is greater than the average value of the cutting level difference (Rδc) of the placement surface 11. Therefore, in the focus ring 1′ according to the other embodiment, heat rising in the plasma treatment chamber is less likely to be transferred from the circumferential surface 13 to the support member 3′. As a result, the temperature difference generated between the placement surface 11 and the circumferential surface 13 becomes small, and the displacement occurring at the inner peripheral side end portion of the placement surface 11 can be suppressed.

The average value of the cutting level difference (Rδc) of the circumferential surface 13 may be, for example, 0.18 μm or more and 0.42 μm or less. When the average value of the cutting level difference (Rδc) of the circumferential surface 13 is 0.18 μm or more, an appropriate friction force is generated between the support member 3′ and the circumferential surface 13. Thus, the focus ring 1′ can be stably fixed to the support member 3′. On the other hand, when the average value of the cutting level difference (Rδc) of the circumferential surface 13 is 0.42 μm or less, upon repeatedly attaching and detaching the focus ring 1′ to and from the support members 3 and 3′, particles detaching from the circumferential surface 13 can be reduced. Therefore, the risk of such particles floating in the plasma treatment chamber can be reduced.

The average value of the root mean square slope (RΔq) in the roughness curve of the circumferential surface 13 may be greater than the average value of the root mean square slope (RΔq) in the roughness curve of the placement surface 11. As described above, when the average value of the root mean square slope (RΔq) in the roughness curve of the circumferential surface 13 is greater than the average value of the root mean square slope (RΔq) in the roughness curve of the placement surface 11, heat rising in the plasma treatment chamber is less likely to be transferred from the circumferential surface 13 to the support member 3′ in the focus ring 1′ according to the other embodiment. As a result, the temperature difference generated between the placement surface 11 and the circumferential surface 13 becomes small, and the displacement occurring at the inner peripheral side end portion of the placement surface 11 can be suppressed.

The average value of the root mean square slope (RΔq) of the circumferential surface 13 is not limited, and may be, for example, 0.066 or more and 0.1 or less. When the average value of the root mean square slope (RΔq) of the circumferential surface 13 is 0.066 or more, an appropriate friction force is generated between the support member 3′ and the circumferential surface 13. Thus, the focus ring 1′ can be stably fixed to the support member 3′. On the other hand, if the average value of the root mean square slope (RΔq) of the circumferential surface 13 is 0.1 or less, upon repeatedly attaching and detaching the focus ring 1′ to and from the support members 3 and 3′, particles detaching from the supported portion 12a on the innermost peripheral side can be reduced. Therefore, the risk of such particles floating in the plasma treatment chamber can be reduced.

The supported portions 12a and 12b may have a greater average value of a mean length (RSm) in the roughness curve than the placement surface 11. When the average value of the mean length (RSm) in the roughness curve of the supported portions 12a and 12b is greater than that of the placement surface 11, the interval between peaks formed by protruding portions in the supported portions 12a and 12b is wide. Thus, the number of contact points with a support surface of the support member 3 supporting the supported portions 12a and 12b becomes small, and heat rising in the plasma treatment chamber is less likely to be transmitted from the supported portions 12a and 12b to the support members 3 and 3′.

In this case, the placement surface 11 has a smaller average value of the mean length (RSm) in the roughness curve than the supported portions 12a and 12b. As a result, an interval between peaks formed by protruding portions in the placement surface 11 is narrow, the number of contact points with the lower surface of the to-be-treated substrate 2 becomes large, and the friction force of the placement surface 11 with respect to the lower surface becomes large. Therefore, even when the to-be-treated substrate 2 is subjected to a plasma treatment and the temperature in the plasma treatment chamber becomes high, the positioning accuracy of the to-be-treated substrate 2 with respect to the focus ring 1′ in a radial direction and a circumferential direction can be sufficiently maintained.

The difference between the average value of the mean length (RSm) of the supported portion 12a and the average value of the mean length (RSm) of the placement surface 11 may be 3 μm or more. In particular, the average value of the mean length (RSm) of the supported portions 12a and 12b may be 20 μm or more and 50 μm or less.

While the average value of the mean length (RSm) of the supported portions 12a and 12b is 20 μm or more, even when a corrosive gas converted into a plasma comes in contact with the supported portions 12a and 12b, particles detached from the supported portions 12a and 12b can be reduced. Therefore, the risk of such particles floating in the plasma treatment chamber can be reduced. When the average value of the mean length (RSm) of the supported portions 12a and 12b is 50 μm or less, the friction force of support surfaces of the support members 3 and 3′ with respect to the supported portions 12a and 12b becomes large. Therefore, even when the temperature in the plasma treatment chamber becomes high, the positioning accuracy of the focus ring 1′ with respect to the support members 3 and 3′ in the radial direction and the circumferential direction can be sufficiently maintained.

A variation coefficient of the mean length (RSm) of the supported portions 12a and 12b is preferably 0.15 or less. When the variation coefficient is 0.15 or less, the variation in the mean length (RSm) of the supported portions 12a and 12b becomes small, and thus, a size of the particles detached from the supported portions 12a and 12b also becomes small.

The cutting level difference (Rδc), the root mean square slope (RΔq), and the mean length (RSm) described above can be measured by using a shape analysis laser microscope (manufactured by Keyence Corporation, VK-X1100 or a successor model of VK-X1100) in accordance with JIS B 0601: 2001. As the measurement conditions, first, a coaxial vertical method is used as the illumination method, the magnification is set to 240 times, a cutoff value μs is not set, a cutoff value λc is set to 0.08 mm, a cutoff value λf is not set, a termination effect correction is set ON, and a measurement range for each point from the placement surface, the supported portion of the back surface, and the circumferential surface that are to be measured is set to, for example, 1420 μm×1070 μm. The roughness may be measured by drawing, in each measurement range, four lines to be measured at substantially equal intervals along a longitudinal direction of the measurement range. The measurement range includes a total of three locations at equal intervals along the circumferential direction, and the length of each line to be measured is, for example, 1280 μm. The average values may be calculated from the measured values obtained for each surface, and the average values may be compared.

The circumferential surface 13 will be described with reference to FIG. 2B. However, the circumferential surface 13 may also be provided in the focus ring 1 according to the embodiment, which is supported by one support member 3. Specifically, when the support member 3 illustrated in FIG. 1B has a shape in which the support member 3 and the support member 3′ illustrated in FIG. 2B are integrally formed, the circumferential surface 13 can also be formed in the focus ring 1 according to the embodiment.

A method of manufacturing the focus ring according to the present disclosure is not limited. For example, the focus ring 1 according to the embodiment is obtained by the following procedure.

As an initial raw material, a powder containing 99.9 mass % or more of Y₂O₃ and at least one selected from the group consisting of AEO (AE being a group 2 element in the periodic table), SiO₂, Fe₂O₃, and Al₂O₃ is prepared. This powder is filled into a grinding mill together with a solvent (ion-exchanged water). The powder is ground to achieve an average particle size of 1 μm or less, and then, an organic binder is added to obtain a slurry. When at least one selected from the group consisting of SiO₂, Fe₂O₃, and Al₂O₃ is contained in 100 mass % of the initial raw material, for example, SiO₂ is 250 mass ppm or less, Fe₂O₃ is 40 mass ppm or less, Al₂O₃ is 50 mass ppm or less, and AEO is 250 mass ppm or less.

The grinding mill is, for example, a ball mill using grinding balls, a vibration mill, or a bead mill. ZrO₂ balls are preferably used as the grinding balls, so that the grinding balls do not mix into the slurry due to wear. The purity of the ZrO₂ balls is preferably 99.9 mass % or more, and particularly preferably 99.99 mass % or more.

The organic binder mentioned above may be paraffin wax, a wax emulsion (wax+emulsifier), polyvinyl alcohol (PVA), polyethylene glycol (PEG), polyethylene oxide (PEO), or the like. The solvent may be distilled water, an organic solvent, or the like.

After preparing the slurry, the slurry is granulated by a granulator such as a spray drying device. The obtained granulated body is formed into a powder compact having an annular flat plate shape by using, for example, an isostatic press molding device. The powder compact is degreased at a temperature of 200 to 1200° ° C. to obtain a degreased body.

The obtained degreased body is placed in a firing jig having a melting point higher than 2000° C., for example, a plate-like firing jig made of high-purity alumina, high-purity magnesia, or the like in an atmosphere containing oxygen such as an air atmosphere. The temperature is increased at an average rate of temperature rise of 20° C./hour or less, and then, the temperature is held at 1500° C. or more and 2000° C. or less for a period of time of 2 hours or more and 5 hours or less to obtain a sintered body. Sintering is promoted at 1000° C. or more, and thus, at 1000° C. or more, the temperature is preferably increased at an average rate of temperature rise of 18° C./hour or less. The term “high purity” refers to a content of 99.9 mass % or more, particularly preferably 99.99 mass % or more.

In the case of firing in an atmosphere containing oxygen, by setting the oxygen partial pressure to 0.05 MPa or more and 1 MPa or less and firing in an atmosphere containing 50 vol % or more of oxygen, particularly in an atmosphere containing 80 vol % of oxygen, the obtained sintered body becomes denser.

The focus ring according to the present disclosure can be obtained by grinding the sintered body on both main surfaces with a grindstone including diamond abrasive grains. A placement surface can be obtained by increasing the grinding allowance in a portion accommodating a substrate to be treated.

In order to obtain a focus ring in which the supported portion of the back surface supported by one support member, the supported portion on the innermost peripheral side of the back surface supported by a plurality of support members, or the circumferential surface extending upward from the back surface and facing the support member has a greater average value of the cutting level difference (Rδc) than the placement surface, a surface serving as the supported portion and a surface serving as the circumferential surface may be ground with a grindstone having a small grain size number (large average particle size), and a surface serving as the placement surface may be ground with a grindstone having a small grain size number (large average particle size), among grindstones including diamond abrasive grains having a grain size of #320 or more and #600 or less. The grain size is in accordance with JIS R6001-2: 2017.

In order to obtain a focus ring in which the average value of the cutting level difference (Rδc) of the supported portion or the circumferential surface is 0.18 μm or more and 0.42 μm or less, for example, the surface serving as the supported portion on the back surface may be ground with a grindstone including diamond abrasive grains having a grain size of #360 or more and #500 or less.

Thus, a focus ring corresponding to the focus ring 1 according to the embodiment was obtained. In the obtained focus ring, the average value of the cutting level difference (Rδc) of the placement surface was determined to be 0.26 μm, and the average value of the cutting level difference (Rδc) of the supported portion was determined to be 0.3 μm. In the obtained focus ring, the average value of the root mean square slope (RΔq) of the placement surface was determined to be 0.06, and the average value of the root mean square slope (RΔq) of the supported portion was determined to be 0.08.

In order to obtain a focus ring in which the supported portion has a greater average value of the mean length (RSm) in the roughness curve than the placement surface, at least a surface of the supported portion is subjected to zero grinding, and the supported portion may be ground more times by zero grinding than the placement surface. Zero grinding means that, at the end of the grinding process, cutting is not performed and only feeding is performed, which is also referred to as spark-out or zero cut. In order to obtain a focus ring in which the average value of the mean length (RSm) of the supported portion is 20 μm or more and 50 μm or less, for example, the supported portion may be subjected to zero grinding for 30 seconds or more and 75 seconds or less.

The focus ring according to the present disclosure is used as a member of a plasma treatment device such as a plasma etching device and a plasma film forming device. Specifically, as illustrated in FIG. 1B and FIG. 2B, the focus ring is used as a member for placing and accommodating the to-be-treated substrate 2.

### REFERENCE SIGNS

1, 1′ Focus ring
11 Placement surface
12 Back surface
12a, 12b Supported portion
13 Circumferential surface
2 To-be-treated substrate
3, 3′ Support member

1. A focus ring, comprising:
a placement surface accommodating a substrate to be treated and facing a lower surface of the substrate to be treated; and
a back surface located on an opposite side to the placement surface, wherein
an average value of a cutting level difference (Rδc) representing a difference between a cutting level at a load-length ratio of 25% in a roughness curve and a cutting level at a load-length ratio of 75% in the roughness curve is greater in a supported portion of the back surface supported by one support member than in the placement surface.

2. The focus ring according to claim 1, wherein
the average value of the cutting level difference (Rδc) of the supported portion is 0.18 μm or more and 0.42 μm or less.

3. The focus ring according to claim 1, wherein
an average value of a root mean square slope (RΔq) in a roughness curve is greater in the supported portion than in the placement surface.

4. The focus ring according to claim 3, wherein
the average value of the root mean square slope (RΔq) of the supported portion is 0.066 or more and 0.1 or less.

5. A focus ring, comprising:
a placement surface accommodating a substrate to be treated and facing a lower surface of the substrate to be treated; and
a back surface located on an opposite side to the placement surface, wherein
an average value of a cutting level difference (Rδc) representing a difference between a cutting level at a load-length ratio of 25% in a roughness curve and a cutting level at a load-length ratio of 75% in the roughness curve is greater in a supported portion on an innermost peripheral side of the back surface supported by a plurality of support members than in the placement surface.

6. The focus ring according to claim 5, wherein
the average value of the cutting level difference (Rδc) of the supported portion on the innermost peripheral side is 0.18 μm or more and 0.42 μm or less.

7. The focus ring according to claim 5, wherein
an average value of a root mean square slope (RΔq) in a roughness curve is greater in the supported portion on the innermost peripheral side than in the placement surface.

8. The focus ring according to claim 7, wherein
the average value of the root mean square slope (RΔq) of the supported portion on the innermost peripheral side is 0.066 or more and 0.1 or less.

9. The focus ring according to claim 1, wherein
an average value of a mean length (RSm) in a roughness curve is greater in the supported portion than in the placement surface.

10. The focus ring according to claim 9, wherein
the average value of the mean length (RSm) of the supported portion is 20 μm or more and 50 μm or less.

11. The focus ring according to claim 1, further comprising:
a circumferential surface extending upward from the back surface and facing the support member, wherein
an average value of a cutting level difference (Rδc) indicating a difference between a cutting level at a load-length ratio of 25% in a roughness curve and a cutting level at a load-length ratio of 75% in the roughness curve, is greater in the circumferential surface than in the placement surface.

12. The focus ring according to claim 11, wherein
the average value of the cutting level difference (Rδc) of the circumferential surface is 0.18 μm or more and 0.42 μm or less.

13. The focus ring according to claim 11, wherein
an average value of a root mean square slope (RΔq) in a roughness curve is greater in the circumferential surface than in the placement surface.

14. The focus ring according to claim 13, wherein
the average value of the root mean square slope (RΔq) of the circumferential surface is 0.066 or more and 0.1 or less.

15. A plasma treatment device, comprising:
the focus ring according to claim 1.

16. A plasma treatment device, comprising:
the focus ring according to claim 5.

17. The focus ring according to claim 5, wherein
an average value of a mean length (RSm) in a roughness curve is greater in the supported portion on the innermost peripheral side than in the placement surface.

18. The focus ring according to claim 5, further comprising:
a circumferential surface extending upward from the back surface and facing the support member, wherein
an average value of a cutting level difference (Rδc) indicating a difference between a cutting level at a load-length ratio of 25% in a roughness curve and a cutting level at a load-length ratio of 75% in the roughness curve, is greater in the circumferential surface than in the placement surface.
